(19) United States
(12) Patent Application Publication
(10) Pub. No.: US 2005/0068733 A1
(43) Pub. Date: Mar. 31, 2005

(54) Computer case cooling system and method therefor

(76) Inventor: Craig Squillante, Scottsdale, AZ (US)

Correspondence Address: WEISS & MOY PC, 4204 NORTH BROWN AVENUE, SCOTTSDALE, AZ, 85251, US

(21) Appl. No.: 10/672,628

(22) Filed: Sep. 26, 2003

(51) Int. Cl. H05K 7/20; G06F 1/20

(52) U.S. Cl. 361/697; 361/687

(57) ABSTRACT

A computer case cooling system has a thermoelectric module. A first fan unit is coupled to the thermoelectric module for discharging heat from a hot side of the thermoelectric module. A second fan unit is coupled to the thermoelectric module for circulating cool air from a cold side of the thermoelectric module.

### BACKGROUND OF THE INVENTION

1. Field of the Invention:

This invention relates generally to computer systems and, more specifically, to a new computer case having a sliding door to allow easy access to the internal components of the computer. The computer case will further have a unique cooling system that will more efficiently cool the interior section of the computer case.

2. Description of the Prior Art:

Almost all desktop personal computers have a main unit which is built in a similar manner. The main unit will have a rectangular shaped case that comprises a chassis frame and an outer shell. The chassis frame typically is a metal frame on which the various computer components and devices are mounted. Usually at one end of the frame several device bays are positioned. Each device bay is designed to hold a computer device, such as a hard disk drive, a CD-ROM drive, a floppy disk drive, CD or DVD drive, or other computer component. The chassis frame also has places or brackets for holding a power supply and various boards, including the computer's motherboard and I/O boards.

An outer shell is positioned over the chassis frame. The outer shell protects the computer components from dust and certain other environmental hazards. The outer shell is generally made out of a light weight metal such as aluminum. The outer shell is generally solid except for a plurality of small holes which may be drilled through the outer shell for ventilation. The outer shell slides on to the chassis frame and is secured to the chassis frame with a plurality of screws.

While present computer cases do work, there are several problems associated with them. First, in order to perform any type of work on the main unit of a desktop computer, one must remove the outer shell from the chassis frame. This requires one to remove all of the screws which hold the outer shell on to the chassis frame. This is very inconvenient and time consuming. Second, the ventilation system in most computers is very basic. Most computer cases generally use a small horsepower fan to cool the components in the computer case. The fan is used to vent the warm air out of the computer case. While the fan does work, a better cooling system will increase the efficiency of the computer system. Third, most computer cases are very dull looking. Many people would prefer to have a computer case that is more stylish looking. A more stylish looking computer case could increase sales to sagging computer sales.

Therefore, a need existed to provide an improved computer case. The improved computer case must overcome the problems associated with prior art computer cases.

### SUMMARY OF THE INVENTION

In accordance with one embodiment of the present invention, it is an object of the present invention to provide an improved computer case.

It is another object of the present invention to provide an improved computer case that overcomes the problems associated with prior art computer cases.

### BRIEF DESCRIPTION OF THE EMBODIMENTS

In accordance with one embodiment of the present invention, a computer case cooling system is disclosed. The computer case cooling system has a thermoelectric module. A first fan unit is coupled to the thermoelectric module for discharging heat from a hot side of the thermoelectric module. A second fan unit is coupled to the thermoelectric module for circulating cool air from a cold side of the thermoelectric module.

The foregoing and other objects, features, and advantages of the invention will be apparent from the following, more particular, description of the preferred embodiments of the invention, as illustrated in the accompanying drawings.

### BRIEF DESCRIPTION OF THE DRAWINGS

The novel features believed characteristic of the invention are set forth in the appended claims. The invention itself, as well as a preferred mode of use, and advantages thereof, will best be understood by reference to the following detailed description of illustrated embodiments when read in conjunction with the accompanying drawings.

FIG. 1 is an elevated perspective view of the computer case of the present invention.

FIG. 2 is a top view of the computer case of the present invention.

FIG. 3 is a side view of the computer case of the present invention.

FIG. 4 is a front view of the computer case of the present invention.

FIG. 5 is a rear view of the computer case of the present invention.

FIG. 6 is a simplified block diagram of the cooling system used in the computer case of the present invention.

FIG. 7 is a simplified functional block diagram of the cooling system used in the computer case of the present invention.

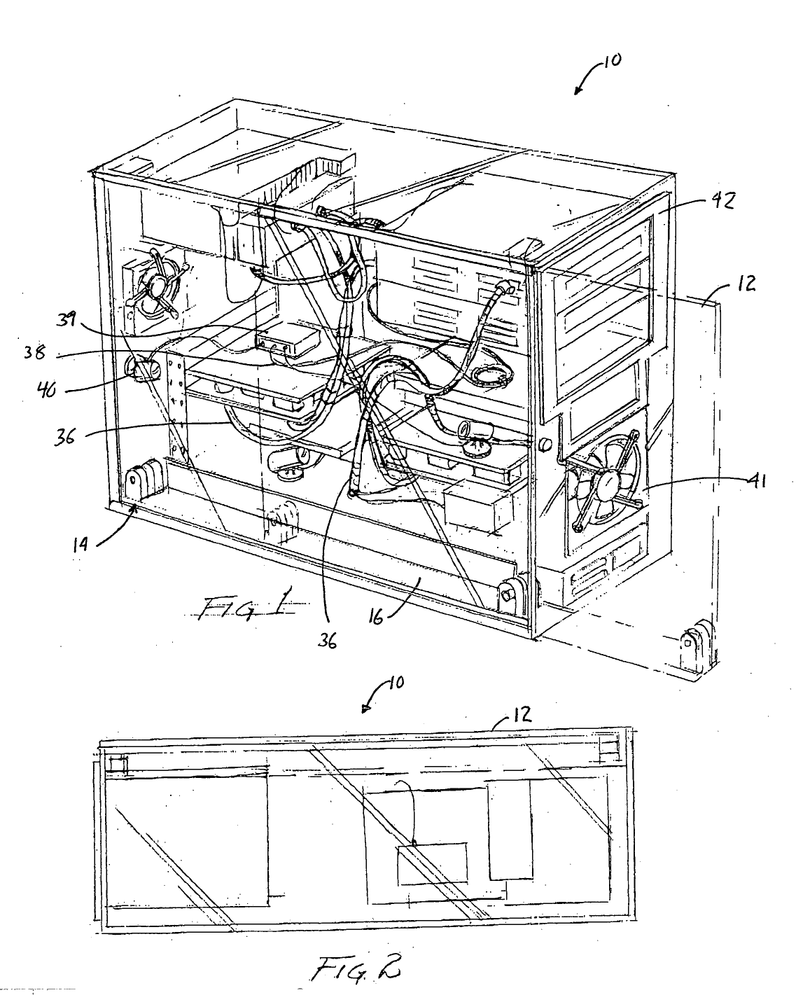

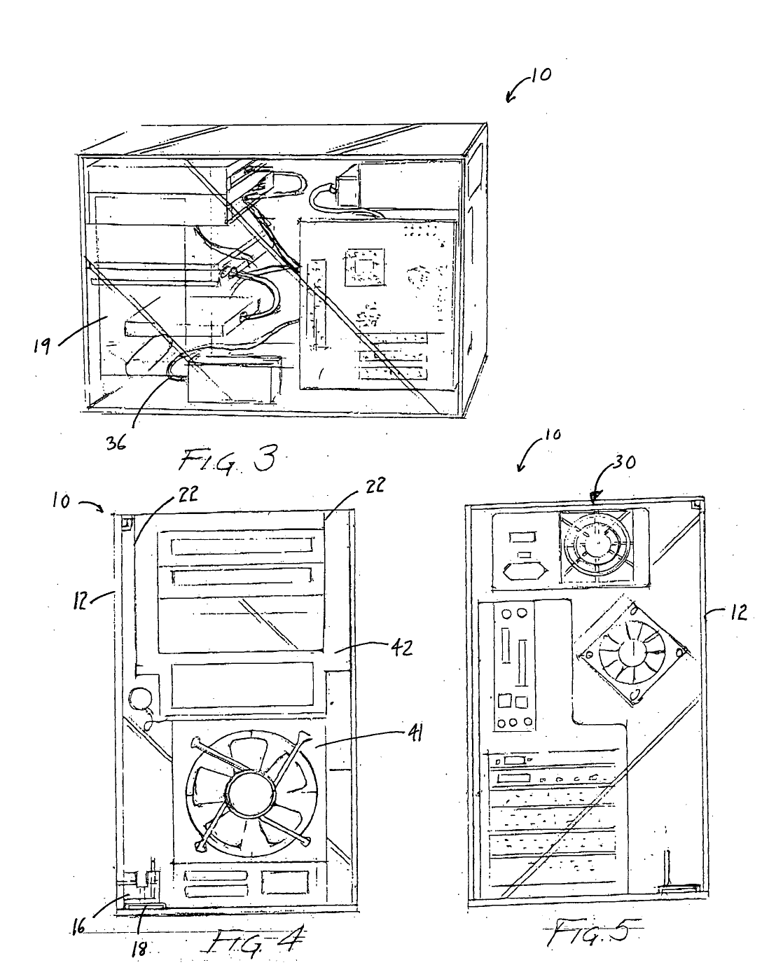

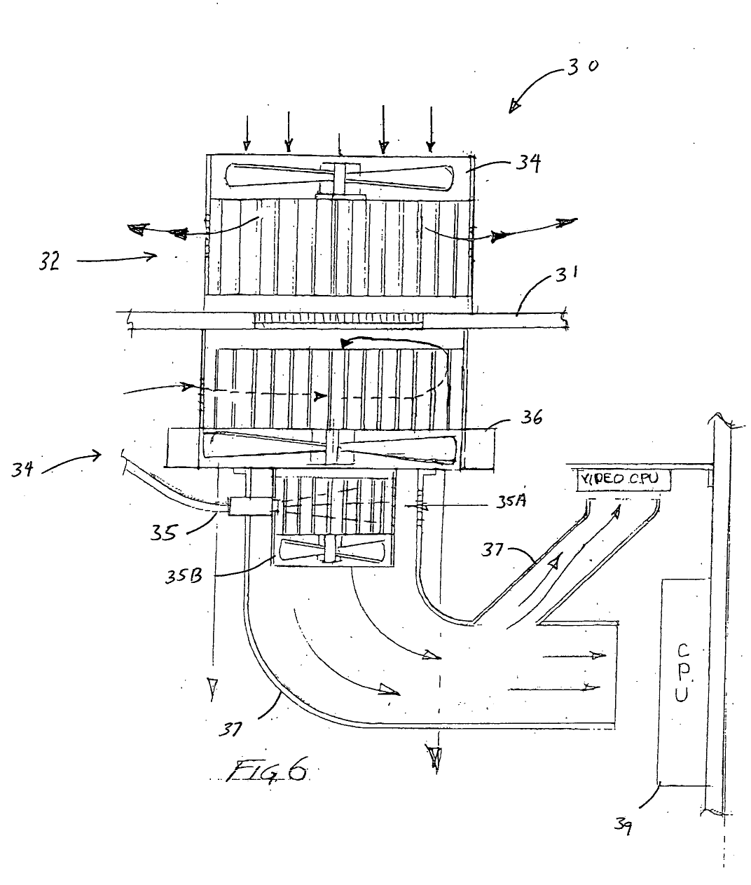

### DETAILED DESCRIPTION OF THE PREFERRED EMBODIMENT

Referring to the Figures, an improved computer case 10 is shown. The computer case 10 is unique in that the entire computer case 10 is transparent. A clear plastic, acrylic material, or the like may be used to construct the computer case 10. By having a transparent computer case 10, one can see the internal components placed inside the computer case 10. The computer case 10 is a rectangular shape box where each side of the box is made from a transparent material. No screws are required to secure the walls of the computer case 10 together. All of the walls, with the exception of one side wall 12, are bonded together. The bond may be an epoxy, heat mold, and the like. The listing of the above should not be seen as to limit the scope of the present invention. Other methods of bonding the walls of the computer case 10 may be used without departing from the spirit and scope of the present invention.

A side wall 12 is moveably coupled to the computer box 10. The side wall 12 allows one to open the computer box 10 and have access to the components internal to the computer box 10 without having to remove a plurality of screws as in the prior art.

Thus, one can more easily gain access to the interior of the computer box 10 in order to work on components inside the computer box 10. The side wall 12 will slide open in order to allow one to have access to the interior of the computer box 10. In general, a sliding mechanism 14 is coupled to the side wall 12. The sliding mechanism 14 will be coupled to a small motor device 20. The motor device 20 is used to open and close the side wall 12. The motor device 20 may be operated via a switch 20A or by a remote control device 20B.

The sliding mechanism 14 may take several different forms. In accordance with one embodiment of the present invention, the sliding mechanism 14 uses a track system 16. The track system 16 allows the side wall 12 to slide forward to expose the interior of the computer box 10. The track system 16 is directly coupled to the side wall 12. A belt or gear and pulley system 18A is coupled to the bottom of the track system 16 and to the motor 20. The belt/gear and pulley system 18A will move in a forward or reverse direction based on the operation of the motor 20. This will allow one to open and close the side wall 12. Alternatively, a retractable arm may be coupled to the bottom of the track system 16 and the motor 20. Operation of the motor 20 will either extend the arm to slide the side wall 12 in an open position or retract the arm to slide the side wall 12 back to a closed position.

A chassis 22 is coupled to the interior of the computer box 10. The chassis 22 is made of the same transparent material as the computer case 10. The chassis 22 is used to hold the various computer components and devices inside the computer case 10. The chassis 22 also has places or brackets for holding a power supply and various boards, including the computer's motherboard and I/O boards.

In order to couple the computer components to the chassis 22, a side access door 19 is formed on the computer case 10. The side access door 19 is formed on the opposite side of the computer case 12 where the side wall 12 is situated. The side access door 19 is used to allow one to secure computer components to the side of the chassis 22 opposite of the side wall 12. The side access door 19 is generally hinged to the computer case 10 to allow one to open and close the side access door 19 and gain access to the inside of the computer case 12.

Internal to the computer case 10 is a unique cooling system 30. The cooling system 30 will provide a constant temperature of approximately 700F to 720F. Sensors may be located in the computer case 10 to monitor the temperature. In general, the sensors will be coupled to the processor 39 of the computer system to measure the temperature of the processor 39. The cooling system 30 will have a control unit 30A which is coupled to the processor 39 of the computer system. The control unit 30A will activate and deactivate the cooling system 30 to keep a constant temperature of approximately 70° F. to 72° F. in the computer case 10.

The cooling system 30 may have one or both of the following: a thermoelectric cooler 32 and/or a Freon cooler 34. The thermoelectric cooler 32 has a heatsink 32A. The heatsink 32A removes heat by exchanging it with air in a more efficient manner.

The heatsink 32A does this by providing more surface area for dissipating the heat. The heatsink 32A has a group of fins 32B.

The longer the fins, and the more of them, the higher the surface area, and the better the efficiency.

A Peltier device 32B (also known as a thermoelectric (TE) module) is coupled to the heatsink 32A. The Peltier device 32B is a small solid-state device generally a few millimeters thick by a few centimeters square. The Peltier device 32B is formed by two ceramic plates with an array of small Bismuth Telluride cubes (“couples”) in between. When a DC current is applied heat is moved from one side of the Peltier device 32B to the other. Thus, one side of the Peltier device 32B will heat up while the other side of the Peltier device 32B will turn cold. The heat from the hot side is then dissipated by the heatsink 32A.

An insulator plate 33 is coupled to the heat sink 32A. The insulator plate 33 is formed around the Peltier device 32B. The insulator plate 33 is used to insulate the Peltier device 32B so that the heat from the hot side of the Peltier device 32B won't affect the coolness of the cold side of the Peltier device 32B. Any type of insulating plate may be used. In accordance with one embodiment of the present invention a canvas based phenolic is used. However, this should not be seen as to limit the scope of the present invention.

A second fan 36A is coupled to the insulator plate 33 and the cold side of the Peltier device 32B. The second fan 36A is coupled to the insulator plate 33 via a second heatsink 36B. The cold air from the cold side of the Peltier device 32B is circulated through the fins 36C of the heatsink 36B, thereby cooling the air even more. The fan 36A then sends the cool air out to cool the computer case 10. The dual fan unit of the thermoelectric cooler 32 causes a vacuum effect which causes the second fan 36A to run. If the temperature in the computer case 10 rises to an elevated temperature, the second fan 36A may be turned on to a higher Revolution Per Minute (RPM) level created by the vacuum effect to cool off the computer case 10.

A freon cooler 34 may also be placed inside the computer case 10. A freon cooler 34 works by having a spray device 35 spray freon onto a heat sink 35A. The freon cools the heat sink 35A causing the fins on the fan 35B to rotate. The cool air from the fan 35B will be blown on the components in the computer case 10 there by cooling the components. Cooler components run more efficiently thereby increasing the efficiency of the computer system. As may be seen more clearly in FIG. 6, air ducts 37 may be used to directly channel the cool air generated by the freon cooler onto components in the computer case 10.

An addition fan unit 41 may be positioned in the front of the computer case 10. The fan unit 41 works in conjunction with the cooling system 30 to create a vacuum effect. Thus, outside air is drawn into the computer case 10 and warm air is expelled from, the computer case 10.

In operation, the cooling system 30 works in the following manner. The Peltier device 32B will draw heat from the components located inside the computer case 10. The heat from the hot side of the Peltier device 32B is then dissipated by the heatsink 32A. The first fans 34 will draw in outside air and blow the heat off the first side of the Peltier device 32B. The hot air will be dissipated through the side exits as indicated by the arrows in FIG. 6.

The cold air from the cold side of the Peltier device 32B is circulated through the fins 36C of the heatsink 36B, thereby cooling the air even more. The fan 36A then sends the cool air out to cool the computer case 10. The thermoelectric cooler 32 is more efficient than prior art system which just have a fan which blows the hot air out of the computer case. By blowing hot air out and cool air into the computer case 10, the computer case 10 will be cooler than prior art cases. By having a cooler computer case 10, the components inside the computer case 10 will run more efficiently.

To even further cool the computer case 10, the freon cooler 34 will spray freon onto the heat sink 35A. The Freon cools the heat sink 35A causing the fins on the fan 35B to rotate. The cool air from the fan 35B will be blown on the components in the computer case 10 there by cooling the components.

In all prior art computer systems, wires are run all through the interior of the computer case. Many times twist ties or other plastic ties are used to group and hold the wires together in order to make the computer case less cluttered. However, the twist ties are still unsightly and have a tendency to break thereby allowing the wires to spread out again. In the computer case 10 of the present invention, wire looms 36 are used to group and hold groups of wire together. Wire looms 36 will better hold the groups of wires togther and do a better job of organizing and covering the wires since the wire looms 36 cover all of the wire. Chrome finish wire looms 36 may be used to provide a sleeker look to the interior of the computer case 10. This is important since the computer case 10 is transparent.

A plurality of different lights may be used in the computer case 10. The lights can be used for artistic purposes as well as to shine and highlight different components inside the computer box 10. For example, lighted tube wiring 38 may be used. The lighted tube wiring 38 may be wrapped around the wire looms 36. Thus one can see the wiring in the dark. The lighted tube wiring 38 may further be positioned through out the computer case 10. Laser lights 40 may also be used. The laser lights 40 may be a beam light or it may be a patterned light. The laser lights 40 may be used for artistic purposes or for shining on a particular component inside the computer case 10. The laser lights 40 may be an LED light like a fisheye LED. However, this should not be taken as to limit the scope of the present invention.

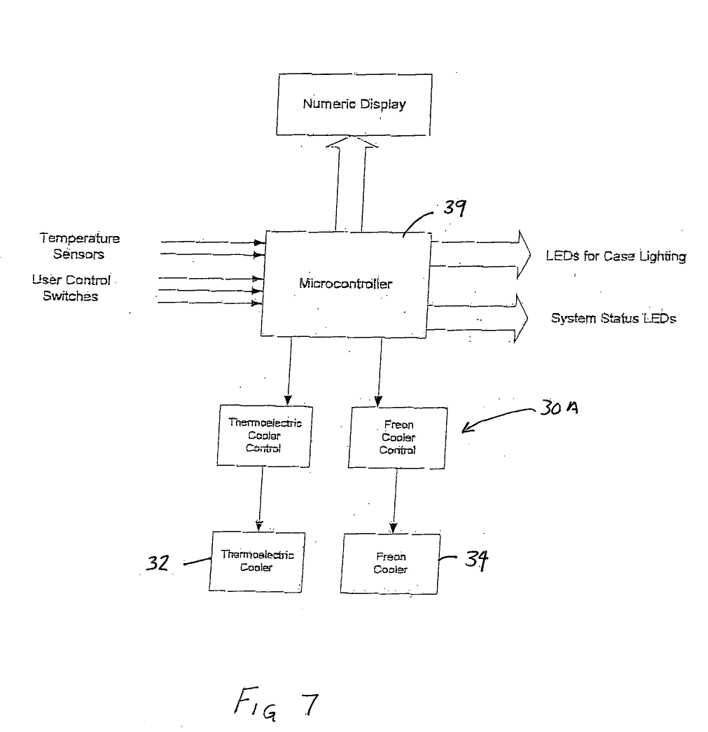

The lighted tube wiring 38 and the laser lights 40 are coupled to a lighting control unit 39. The lighting control unit 39 will provide power to the lighted tube wiring 38 and the laser lights 40. The lighting control unit 39 will further allow one to control the lighted tube wiring 38 and the laser lights 40. Thus, one can turn on and off different lights in the computer case 10. The lighting control unit 39 is generally the main processor unit of the computer case 10. As can be seen more clearly in FIG. 7, the processor unit 39 can also be used to control and display status lights for the computer case 10, LEDs for case lighting, a numeric display to show processor speed or the temperature of the computer case 10, etc. The processor 39 can further be used to control the cooling system 30 so that the computer case 10 remains at a constant temperature.

A plurality of different colored face plates 42 may be coupled to the exterior of the computer case 10. The face plates 42 are used to cover up openings where a DVD drive, a CD drive, a floppy drive, and the like will be positioned in the computer case 10. The face plates 42 are removable. Thus, one can easily remove the face plate 42 and insert a different face plate 42 of a different color. By having different color face plates 42, one can customize the look and appearance of the computer case 10.

While the invention has been particularly shown and described with reference to preferred embodiments thereof, it will be understood by those skilled in the art that the foregoing and other changes in form and details may be made therein without departing from the spirit and scope of the invention.

1. A cooling system for a computer case comprising:
a thermoelectric module;
a first fan unit for discharging heat from a hot side of the thermoelectric module; and
a second fan unit for circulating cool air from a cold side of the thermoelectric module.

2. A cooling system for a computer case in accordance with claim 1 further comprising an insulator plate positioned around the thermoelectric module for preventing heat from the hot side of the thermoelectric module from going to the cold side of the thermoelectric module.

3. A cooling system for a computer case in accordance with claim 1 wherein the first fan unit comprises:
a first heatsink coupled to the hot side of the thermoelectric module for dissipating hat from the hot side of the thermoelectric module; and
a first fan coupled to the first heat sink for dissipating the heat from the first heat sink and the hot side of the thermoelectric module.

4. A cooling system for a computer case in accordance with claim 1 wherein the second fan unit comprises:
a second heatsink coupled to the cold side of the thermoelectric module; and
a second fan coupled to the second heat sink for dissipating the cool air from the second heat sink and the cold side of the thermoelectric module.

5. A cooling system for a computer case in accordance with claim 4 further comprising molding coupled to the second heatsink for circulating the cool air around the heat sink to further cool the air prior to the second fan dissipating the cool air from the second heat sink and the cold side of the thermoelectric module.

6. A cooling system for a computer case in accordance with claim 1 further comprising a freon cooler coupled to the second fan unit for circulating colder air inside the computer case.

7. A cooling system for a computer case in accordance with claim 6 wherein the freon cooler comprises:
a freon storage device;
a spray mechanism coupled to the freon storage device for dispensing the freon stored inside the freon storage device;
a third heat sink on which the spray mechanism will dispense the freon onto; and
a third fan coupled to the third heat sink for circulating the colder air from the freon cooler inside the computer case.

8. A cooling system for a computer case in accordance with claim 7 further comprising ducting coupled to the freon cooler for directing the colder air from the freon cooler to a processor unit of the computer case.

9. A cooling system for a computer case comprising:
a thermoelectric module;
a first fan unit for discharging heat from a hot side of the thermoelectric module;
a second fan unit for circulating cool air from a cold side of the thermoelectric module;
an insulator plate positioned around the thermoelectric module for preventing heat from the hot side of the thermoelectric module from going to the cold side of the thermoelectric module; and
a freon cooler coupled to the second fan unit for generating and circulating colder air inside the computer case.

10. A cooling system for a computer case in accordance with claim 9 wherein the first fan unit comprises:
a first heatsink coupled to the hot side of the thermoelectric module for dissipating hat from the hot side of the thermoelectric module; and
a first fan coupled to the first heat sink for dissipating the heat from the first heat sink and the hot side of the thermoelectric module.

11. A cooling system for a computer case in accordance with claim 9 wherein the second fan unit comprises:
a second heatsink coupled to the cold side of the thermoelectric module; and
a second fan coupled to the second heat sink for dissipating the cool air from the second heat sink and the cold side of the thermoelectric module.

12. A cooling system for a computer case in accordance with claim 11 further comprising molding coupled to the second heatsink for circulating the cool air around the heat sink to further cool the air prior to the second fan dissipating the cool air from the second heat sink and the cold side of the thermoelectric module.

13. A cooling system for a computer case in accordance with claim 9 wherein the freon cooler comprises:
a freon storage device;
a spray mechanism coupled to the freon storage device for dispensing the freon stored inside the freon storage device;
a third heat sink on which the spray mechanism will dispense the freon onto; and
a third fan coupled to the third heat sink for circulating the colder air from the freon cooler inside the computer case.

14. A cooling system for a computer case in accordance with claim 13 further comprising ducting coupled to the freon cooler for directing the colder air from the freon cooler to a processor unit of the computer case.

15. A cooling system for a computer case comprising:
a thermoelectric module having a hot side and a cold side;
a first fan unit for discharging heat from the hot side of the thermoelectric module wherein the first fan unit comprises:
a first heatsink coupled to the hot side of the thermoelectric module for dissipating hat from the hot side of the thermoelectric module; and
a first fan coupled to the first heat sink for dissipating the heat from the first heat sink and the hot side of the thermoelectric module;
a second fan unit for circulating cool air from the cold side of the thermoelectric module wherein the second fan unit comprises:
a second heatsink coupled to the cold side of the thermoelectric module; and
a second fan coupled to the second heat sink for dissipating the cool air from the second heat sink and the cold side of the thermoelectric module;
an insulator plate positioned around the thermoelectric module for preventing heat from the hot side of the thermoelectric module from going to the cold side of the thermoelectric module; and
a freon cooler coupled to the second fan unit for generating and circulating colder air inside the computer case wherein the freon cooler comprises:
a freon storage device;
a spray mechanism coupled to the freon storage device for dispensing the freon stored inside the freon storage device;
a third heat sink on which the spray mechanism will dispense the freon onto; and
a third fan coupled to the third heat sink for circulating the colder air from the freon cooler inside the computer case.

16. A cooling system for a computer case in accordance with claim 15 further comprising molding coupled to the second heatsink for circulating the cool air around the heat sink to further cool the air prior to the second fan dissipating the cool air from the second heat sink and the cold side of the thermoelectric module.

17. A cooling system for a computer case in accordance with claim 15 further comprising ducting coupled to the freon cooler for directing the colder air from the freon cooler to a processor unit of the computer case.
